(19) United States
(12) Patent Application Publication
(10) Pub. No.: US 2009/0194816 A1
(43) Pub. Date: Aug. 6, 2009

(54) SEMICONDUCTOR DEVICE AND METHOD OF FABRICATING THE SAME

(75) Inventor: Hiroyuki Onoda, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Minato-ku, Tokyo (JP)

(21) Appl. No.: 12/364,070

(22) Filed: Feb. 2, 2009

(30) Foreign Application Priority Data
Feb. 1, 2008 (JP) 2008-22599

(51) Int. Cl. H01L 27/092; H01L 21/8238

(52) U.S. Cl. 257/369; 438/199; 257/255; 257/E27.062; 257/E21.632

(57) ABSTRACT

A semiconductor device according to one embodiment includes: an n-type transistor comprising a first gate electrode formed on a semiconductor substrate via a first gate insulating film, a first spacer formed on a side face of the first gate electrode, a first channel region formed in the semiconductor substrate under the first gate insulating film, a first source/drain region formed on both sides of the first channel region and comprising an extension region formed by a conductivity type impurity segregated on the first channel side, and a first silicide layer formed on the first source/drain region so as to contact with the first spacer; a p-type transistor comprising a second gate electrode formed on the semiconductor substrate via a second gate insulating film, a second spacer formed on a side face of the second gate electrode, a gate sidewall formed on a side face of the second spacer, a second channel region formed in the semiconductor substrate under the second gate insulating film, a second source/drain region formed on both sides of the second channel region and comprising an extension region on the second channel region side, and a second silicide layer formed on the second source/drain region so as to separate from the second spacer; a tensile stress film formed on the n-type transistor so as to contact with a side face of the first spacer for generating a tensile strain in channel direction in the first channel region; and a compressive stress film formed on the p-type transistor so as to contact with a side face of the gate sidewall for generating a compressive strain in channel direction in the second channel region.

### CROSS-REFERENCE TO RELATED APPLICATIONS

This application is based upon and claims the benefit of priority from prior Japanese Patent Application No. 2008-022599, filed on Feb. 1, 2008, the entire contents of which are incorporated herein by reference.

### BACKGROUND

As a conventional semiconductor device, a transistor is known in which only an offset spacer (a narrow gate sidewall) is formed on a side face of a gate electrode without forming a normal gate sidewall and a silicide layer is formed on an upper surface of a source/drain region.

According to this semiconductor device, a silicide layer is formed in a region in the vicinity of an edge of an extension region of a source/drain region on a channel region side. Therefore, a conductivity type impurity in the extension region is pushed to the vicinity of an interface between the extension region and a semiconductor substrate by the silicide layer, and is thereby segregated. As a result, since an impurity profile in the extension region in the vicinity of the interface is highly concentrated as well as steep and interface parasitic resistance decreases, a transistor on-state current is improved. Note that, such technique is called a segregation Schottky technique, etc., and such structure is called a DSS (Dopant Segregated Schottky) structure, etc.

In addition, a semiconductor device, in which the DSS structure is applied to an n-type or p-type transistor and a strained-Si structure using an epitaxially grown SiGe crystal as a source/drain region is further applied to a p-type transistor, has been reported. The semiconductor device, for example, is disclosed in non-patent literary document of Hung-Wei Chen et al., Symposium on VLSI Technology Digest of Technical Papers, 2007, pp. 118-119).

According to the semiconductor device disclosed in the non-patent literary document of Hung-Wei Chen et al., Symposium on VLSI Technology Digest of Technical Papers, 2007, pp. 118-119, it is possible to improve an on-state current of the n-type and p-type transistors by applying the DSS structure, and is possible to improve carrier (hole) mobility in a channel region by generating a compressive strain in a channel direction in the channel region of the p-type transistor by applying the strained-Si structure.

### BRIEF SUMMARY

A semiconductor device according to one embodiment includes: an n-type transistor comprising a first gate electrode formed on a semiconductor substrate via a first gate insulating film, a first spacer formed on a side face of the first gate electrode, a first channel region formed in the semiconductor substrate under the first gate insulating film, a first source/drain region formed on both sides of the first channel region and comprising an extension region formed by a conductivity type impurity segregated on the first channel side, and a first silicide layer formed on the first source/drain region so as to contact with the first spacer; a p-type transistor comprising a second gate electrode formed on the semiconductor substrate via a second gate insulating film, a second spacer formed on a side face of the second gate electrode, a gate sidewall formed on a side face of the second spacer, a second channel region formed in the semiconductor substrate under the second gate insulating film, a second source/drain region formed on both sides of the second channel region and comprising an extension region on the second channel region side, and a second silicide layer formed on the second source/drain region so as to separate from the second spacer; a tensile stress film formed on the n-type transistor so as to contact with a side face of the first spacer for generating a tensile strain in channel direction in the first channel region; and a compressive stress film formed on the p-type transistor so as to contact with a side face of the gate sidewall for generating a compressive strain in channel direction in the second channel region.

A semiconductor device according to another embodiment includes: an n-type transistor comprising a first gate electrode formed on a semiconductor substrate via a first gate insulating film, a first spacer formed on a side face of the first gate electrode, a first channel region formed in the semiconductor substrate under the first gate insulating film, a first source/drain region formed on both sides of the first channel region and comprising an extension region formed by a conductivity type impurity segregated on the first channel side, and a first silicide layer formed on the first source/drain region so as to contact with the first spacer; and a p-type transistor comprising a second gate electrode formed on the semiconductor substrate via a second gate insulating film, a second spacer formed on a side face of the second gate electrode, a gate sidewall formed on a side face of the second spacer, a second channel region formed in the semiconductor substrate under the second gate insulating film, an epitaxial crystal layer formed on both sides of the second channel region, a second source/drain region formed on both sides of the second channel region so as to at least partially overlap with the epitaxial crystal layer and comprising an extension region on the second channel region side, and a second silicide layer formed on the second source/drain region so as to separate from the semiconductor substrate and the second spacer.

A method of fabricating a semiconductor device according to another embodiment includes: respectively forming first and second gate electrodes in n-type and p-type transistor regions on a semiconductor substrate via gate insulating films; forming first and second spacers on side faces of the first and second gate electrodes; respectively forming extension regions of the first and second source/drain regions by implanting an impurity into the n-type and p-type transistor regions on the semiconductor substrate using the first and second spacers and the first and second gate electrodes as a mask; selectively forming a gate sidewall on a side face of the second spacer; respectively forming first and second silicide layers in a region exposed on both sides of the first spacer in the n-type transistor region and a region exposed on both sides of the gate sidewall in the p-type transistor region of the semiconductor substrate; forming a tensile stress film including a tensile stress on the n-type and p-type transistor regions so as to contact with a side face of the first spacer and a side face of the gate sidewall; selectively removing a portion of the tensile stress film located on the p-type transistor region; and forming a compressive stress film including a compressive strain on the p-type transistor region so as to contact with the side face of the gate sidewall after selectively removing the portion of the tensile stress film located on the p-type transistor region.

### BRIEF DESCRIPTION OF THE DRAWING

FIG. 1 is a cross sectional view showing a semiconductor device according to a first embodiment;

FIGS. 2A to 2H are cross sectional views showing processes for fabricating the semiconductor device according to the first embodiment;

FIG. 3 is a cross sectional view showing a semiconductor device according to a second embodiment; and

FIGS. 4A to 4F are cross sectional views showing processes for fabricating the semiconductor device according to the second embodiment.

### DETAILED DESCRIPTION

### First Embodiment

### (Structure of Semiconductor Device)

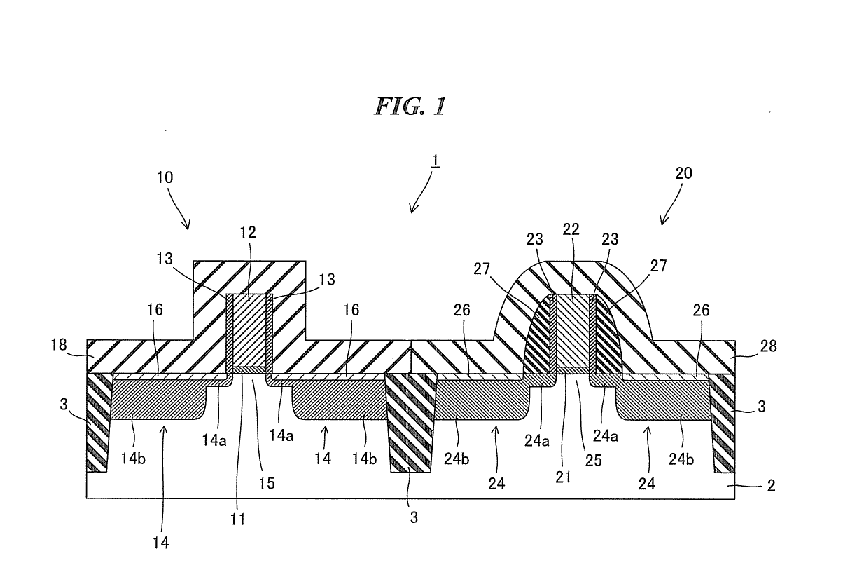

FIG. 1 is a cross sectional view showing a semiconductor device according to a first embodiment. A semiconductor device 1 has an n-type transistor 10 and a p-type transistor 20 on a semiconductor substrate 2, and the n-type transistor 10 and the p-type transistor 20 are electrically isolated from each other by an element isolation region 3.

A bulk Si substrate, an SOI (Silicon on Insulator) substrate, etc., may be used for the semiconductor substrate 2.

The element isolation region 3 is made of, e.g., an insulating film such as SiO₂, etc., and has a STI (Shallow Trench Isolation) structure.

The n-type transistor 10 is schematically configured to have a gate electrode 12 formed on the semiconductor substrate 2 via a gate insulating film 11, an offset spacer 13 formed on a side face of the gate electrode 12, a channel region 15 formed in the semiconductor substrate 2 under the gate insulating film 11, a source/drain region 14 formed in a region in the semiconductor substrate 2 sandwiching the channel region 15 and having an extension region 14a formed on the channel region 15 side by a segregated conductivity type impurity, and a silicide layer 16 formed on the source/drain region 14 so as to contact with the offset spacer 13.

The p-type transistor 20 is schematically configured to have a gate electrode 22 formed on the semiconductor substrate 2 via a gate insulating film 21, an offset spacer 23 formed on a side face of the gate electrode 22, a gate sidewall 27 formed on a side face of the offset spacer 23, a channel region 25 formed in the semiconductor substrate 2 under the gate insulating film 21, a source/drain region 24 formed in a region in the semiconductor substrate 2 sandwiching the channel region 25 and having an extension region 24a formed on the channel region 25 side, and a silicide layer 26 formed on the source/drain region 24 so as to separate from the offset spacer 23.

The gate insulating films 11 and 21 are made of, e.g., SiO₂, SiN, SiON, or a high-dielectric material (e.g., an Hf-based material such as HfSiON, HfSiO or HfO, etc., a Zr-based material such as ZrSiON, ZrSiO or ZrO, etc., and a Y-based material such as Y₂O₃, etc.)

The gate electrodes 12 and 22 are made of a Si-based polycrystalline such as polycrystalline Si or polycrystalline SiGe, etc., containing a conductivity type impurity. An n-type impurity such as As or P, etc., is used for the gate electrode 12 and a p-type impurity such as B or BF₂, etc., is used for the gate electrode 22. In addition, when the gate electrodes 12 and 22 are made of a Si-based polycrystalline, a silicide layer may be formed on an upper portion thereof. Alternatively, the gate electrodes 12 and 22 may be a metal gate electrode made of W, Ta, Ti, Hf, Zr, Ru, Pt, Ir, Mo or Al, etc., or a compound thereof, etc. Furthermore, the gate electrodes 12 and 22 may have a structure in which a metal gate electrode and a Si-based polycrystalline electrode are laminated.

The offset spacers 13 and 23 are made of an insulating material such as SiO₂ or SiN, etc. Thicknesses of the offset spacers 13 and 23 affect formation positions of the extension regions 14a and 24a of the source/drain regions 14 and 24 and the silicide layer 16, etc., and are preferably no less than 3 nm, nor more than 12 nm.

The gate sidewall 27 may have a single layer structure made of, e.g., SiN, a structure of two layer made of, e.g., SiN and SiO₂, or furthermore, a structure of three or more layers.

The source/drain region 14 includes a shallow extension region 14a and a deep region 14b, and is formed by implanting an n-type impurity such as As or P, etc., into the n-type transistor 10 of the semiconductor substrate 2. Meanwhile, the source/drain region 24 includes a shallow extension region 24a and a deep region 24b, and is formed by implanting a p-type impurity such as B or BF₂, etc., into the p-type transistor 20 of the semiconductor substrate 2.

The silicide layers 16 and 26 are made of a metal such as Ni, Pt, Co, Er, Y, Yb, Ti, Pd, NiPt or CoNi, etc, with a compound containing Si, and are formed on exposed portions of upper surfaces of the source/drain regions 14 and 24. The silicide layer 16 is formed on both sides of the offset spacer 13 so as to contact with the offset spacer 13. In addition, the silicide layer 26 is formed on both sides of the gate sidewall 27 so as to contact with the gate sidewall 27.

The silicide layer 16 is formed in a region in the vicinity of an edge of the extension region 14a of the source/drain region 14 on the channel region 15 side (the DSS structure). Therefore, an n-type conductivity impurity in the extension region 14a is pushed to the vicinity of an interface between the extension region 14a and the semiconductor substrate 2 by the silicide layer 16, and is segregated. As a result, since an impurity profile in the extension region 14a in the vicinity of the interface is highly concentrated as well as steep and interface parasitic resistance decreases, it is possible to improve an on-state current of the n-type transistor 10.

A tensile stress film 18 is formed on the n-type transistor 10 so as to contact with a side face of the offset spacer 13. In addition, the tensile stress film 18 includes a tensile stress and has a function to generate a tensile strain in a channel direction in the channel region 15. Meanwhile, a compressive stress film 28 is formed on the p-type transistor 20 so as to contact with a side face of the gate sidewall 27. In addition, the compressive stress film 28 includes a compressive stress and has a function to generate a compressive strain in a channel direction in the channel region 25.

The tensile stress film 18 and the compressive stress film 28 are made of, e.g., a silicon nitride film formed by a plasma CVD (Chemical Vapor Deposition) method. In this case, it is possible to form the tensile stress film 18 and the compressive stress film 28 separately by controlling an operating condition of a plasma CVD apparatus. For example, a hydrogen concentration in the silicon nitride film is controlled by appropriately setting, e.g., RF (Radio Frequency) power of the plasma CVD apparatus, and it is thereby possible to separately form the tensile stress film 18 having a low hydrogen concentration and the compressive stress film 28 having a high hydrogen concentration.

When the tensile strain in the channel direction is generated in the channel region 15 by the tensile stress film 18, electron mobility in the channel region 15 is improved. Meanwhile, when the compressive strain in the channel direction is generated in the channel region 25 by the compressive stress film 28, hole mobility in the channel region 25 is improved.

An example of a method of fabricating a semiconductor device 1 according to this embodiment will be described hereinafter.

### (Fabrication of Semiconductor Device)

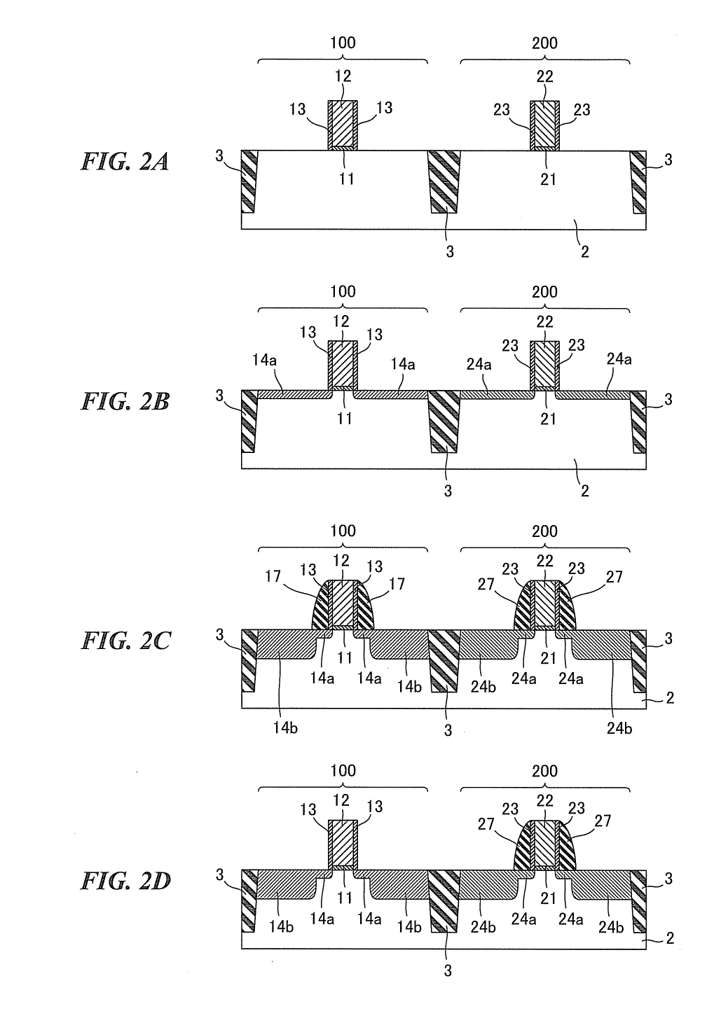

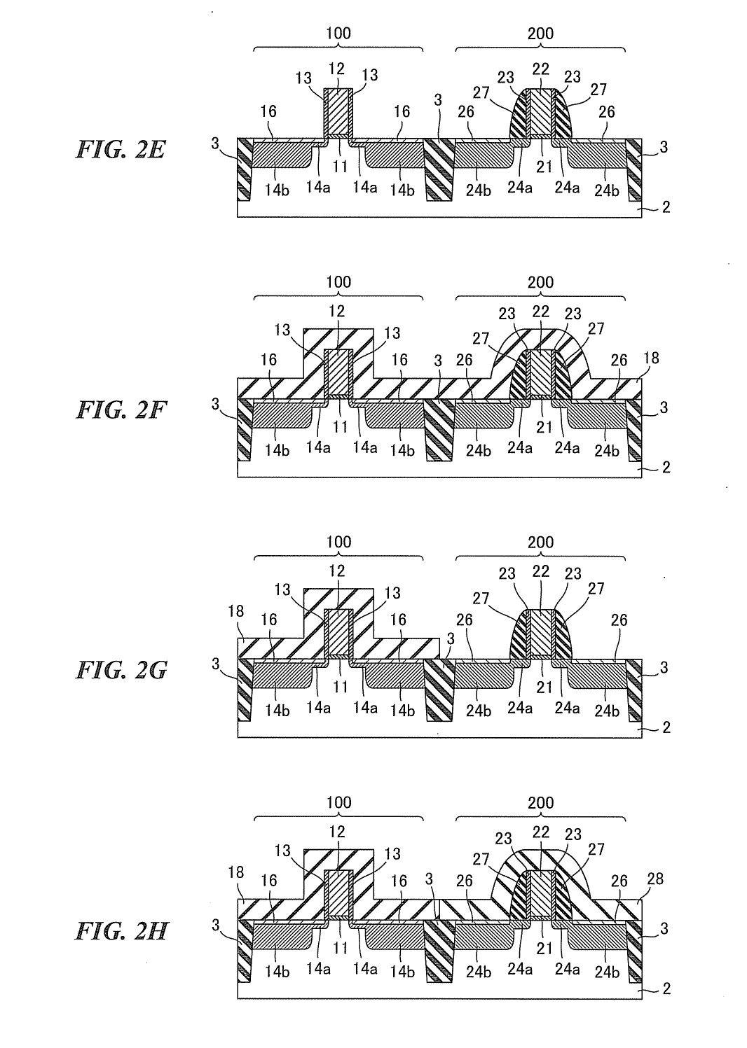

FIGS. 2A to 2H are cross sectional views showing processes for fabricating the semiconductor device according to the first embodiment.

Firstly, as shown in FIG. 2A, on the semiconductor substrate 2, after isolating an n-type transistor region 100 for forming the n-type transistor 10 from a p-type transistor region 200 for forming the p-type transistor 20 by forming the element isolation region 3, the gate insulating film 11, the gate electrode 12 and the offset spacer 13 are formed in the n-type transistor region 100, and the gate insulating film 21, the gate electrode 22 and the offset spacer 23 are formed in the p-type transistor region 200.

Next, as shown in FIG. 2B, a conductivity type impurity is implanted into the semiconductor substrate 2 by an ion implantation procedure using the gate electrodes 12 and 22 and the offset spacers 13 and 23 as a mask, thereby forming the extension region 14a of the source/drain region 14 in the n-type transistor region 100 and the extension region 24a of the source/drain region 24 in the p-type transistor region 200. Here, an n-type impurity such as As or P, etc., is implanted into the n-type transistor region 100 and a p-type impurity such as B, BF₂ or In, etc., is implanted into the p-type transistor region 200.

Next, as shown in FIG. 2C, after respectively forming gate sidewalls 17 and 27 on the side faces of the offset spacers 13 and 23, a conductive type impurity is implanted into the semiconductor substrate 2 by the ion implantation procedure using the gate sidewalls 17 and 27 as a mask, thereby forming the deep region 14b of the source/drain region 14 in the n-type transistor region 100 and the deep region 24b of the source/drain region 24 in the p-type transistor region 200.

Here, for example, after depositing a material film of the gate sidewalls 17 and 27 such as SiO₂, etc., so as to cover the side faces of the offset spacers 13 and 23, the material film is etched by a RIE (Reactive Ion Etching) method, which results in that the gate sidewalls 17 and 27 are formed. In addition, the deep region 14b is formed by implanting an n-type impurity such as As or P, etc., into the n-type transistor region 100 and the deep region 24b is formed by implanting a p-type impurity such as B, BF₂ or In, etc., into the p-type transistor region 200.

Next, as shown in FIG. 2D, the gate sidewall 17 is removed by etching. At this time, a mask is formed in the p-type transistor region 200 so that the etching does not reach the gate sidewall 27. Note that, it is preferable that the gate sidewall 17 and the offset spacer 13 have a certain level of etching selectivity in order to leave the offset spacer 13 without being removed.

Next, as shown in FIG. 2E, the silicide layers 16 and 26 are formed. A metal film made of Ni, etc., is deposited by sputtering so as to cover the exposed portions of the upper surfaces of the source/drain regions 14 and 24, and silicidation reaction is generated on an interface between the metal film and a gate electrode and an interface between the metal film and a source/drain region by RTA at 400-500° C., which results in that the silicide layers 16 and 26 are formed. And then, an unreacted portion of the metal film is removed by etching with a mixed solution of sulfuric acid and hydrogen peroxide solution.

At this time, since the upper surface of the source/drain region 14 is exposed on both sides of the offset spacer 13, the silicide layer 16 is formed contacting with the offset spacer 13. Meanwhile, since the upper surface of the source/drain region 24 is exposed on both sides of the gate sidewall 27, the silicide layer 26 is formed contacting with the gate sidewall 27 (separating from the offset spacer 23).

Next, as shown in FIG. 2F, the tensile stress film 18 is formed on the whole surface of the semiconductor substrate 2 by the plasma CVD method, etc.

Next, as shown in FIG. 2G, a portion of the tensile stress film 18 located in the p-type transistor region 200 is selectively removed by using a lithography method and the RIE method, etc.

In this process, when the gate sidewall 27 is not formed on the side face of the offset spacer 23, the offset spacer 23 may be removed together with the tensile stress film 18 for the reason that a width of the offset spacer 23 is thin, etc.

If the offset spacer 23 is removed, the gate electrode 22 and the gate insulating film 21 may be damaged by the RIE or chemicals, etc. Especially, when the gate electrode 22 is a metal gate electrode, the damage is increased. Furthermore, when the gate electrode 22 is a metal gate electrode, metallic contamination to peripheral members may occur due to a metal composing the metal gate electrode.

On the other hand, in the embodiment, since the offset spacer 23 is protected by the gate sidewall 27, the offset spacer 23 is not removed with the tensile stress film 18. Therefore, it is possible to avoid the above-mentioned problem.

Next, as shown in FIG. 2H, the compressive stress film 28 is formed in the p-type transistor region 200 by the plasma CVD method, etc. Here, for example, after forming the compressive stress film 28 on the whole surface of the semiconductor substrate 2, a portion thereof located in the n-type transistor region 100 is selectively removed by using the lithography method and the RIE method, etc.

In this process, when the gate sidewall 27 is not formed on the side face of the offset spacer 23, the compressive stress film 28 is formed covering the side face of the offset spacer 23 and the upper surface of the semiconductor substrate 2. However, since an angle defined by the side face of the offset spacer 23 and the upper surface of the semiconductor substrate 2 is a substantially right angle, the compressive stress film 28 having inferior coatability compared with the tensile stress film 18 cannot appropriately cover the side face of the offset spacer 23 and the upper surface of the semiconductor substrate 2. Therefore, a strain generated in the channel region 25 by the compressive stress film 28 may be insufficient.

On the other hand, in the embodiment, the gate sidewall 27 is formed on side face of the offset spacer 23. Since the angle defined by the side face of the gate sidewall 27 and the upper surface of the semiconductor substrate 2 is larger than the right angle, and moreover, the side face of the gate sidewall 27 is curved, it is possible to appropriately cover the side face of the gate sidewall 27 and the upper surface of the semiconductor substrate 2 by the compressive stress film 28. Therefore, it is possible to effectively generate a strain in the channel region 25 by the compressive stress film 28.

### Effect of the First Embodiment

According to the first embodiment, since the gate sidewall 27 is located on the side face of the offset spacer 23 in the process of forming the compressive stress film 28 in the p-type transistor region 200, it is possible to appropriately cover the side face of the gate sidewall 27 and the upper surface of the semiconductor substrate 2 by the compressive stress film 28, thereby effectively generating a strain in the channel region 25. If the p-type transistor 20 has the DSS structure, since the gate sidewall 27 is not formed, the side face of the gate sidewall 27 and the upper surface of the semiconductor substrate 2 may not be appropriately covered by the compressive stress film 28.

In addition, since the offset spacer 23 is protected by the gate sidewall 27 in the process of removing the tensile stress film 18 in the p-type transistor region 200, the offset spacer 23 is not removed with the tensile stress film 18. As a result, it is possible to suppress damages generated in the gate electrode 22 and the gate insulating film 21 due to the RIE or the chemicals, etc. Especially, when the gate electrode 22 includes a metal gate electrode, since the damage generated in the metal gate electrode portion is large, this effect is more important. Furthermore, when the gate electrode 22 includes a metal gate electrode, the generation of the metallic contamination to the peripheral members due to the metal composing the metal gate electrode is suppressed by the gate sidewall 27. If the p-type transistor 20 has the DSS structure, since the gate sidewall 27 is not formed, the offset spacer 23 may be removed together with the tensile stress film 18.

Meanwhile, it is possible to improve performance of the n-type transistor 10 by configuring the n-type transistor 10 to have the DSS structure, without providing a gate sidewall. It is known that an effect of improving an on-state current by the DSS structure is large in an n-type transistor compared with a p-type transistor.

### Second Embodiment

The semiconductor device 1 according to the second embodiment is different from the first embodiment in that the deep region 24b of the source/drain region 24 of the p-type transistor 20 is formed in an epitaxial crystal layer 29. Note that, the explanation will be omitted for the points same as the first embodiment.

### (Structure of Semiconductor Device)

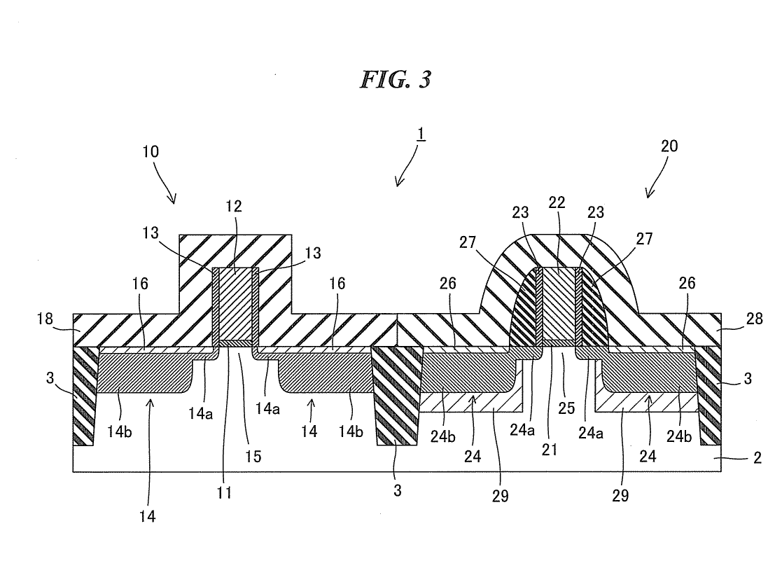

FIG. 3 is a cross sectional view showing a semiconductor device according to a second embodiment.

The epitaxial crystal layer 29 is formed in a trench formed in a region of the p-type transistor 20 of the semiconductor substrate 2 by epitaxially growing a crystal having a lattice constant larger than that of a crystal composing the semiconductor substrate 2.

Since the epitaxial crystal layer 29 is made of a crystal having a lattice constant larger than that of the crystal composing the semiconductor substrate 2, lattice strain caused by the difference between these lattice constants is generated in the semiconductor substrate 2, and a compressive strain in a channel direction is generated in the channel region 25. Therefore, for example, when the channel direction of the channel region 25 is <110> or <100>, etc., the hole mobility in the channel region 25 is improved, thereby improving the performance of the p-type transistor 20.

For example, when the semiconductor substrate 2 is composed of a Si crystal, it is possible to use a SiGe crystal as the epitaxial crystal layer 29. Note that, when the SiGe crystal is used, it is preferable that a Ge concentration is, e.g., 10-30 At %. This is because a strain generated in the channel region 25 tends to be insufficient at less than 10 At % and a crystal defect in the SiGe crystal tends to increase at over 30 At %.

The gate sidewall 27 has a width such that a portion thereof is located on the epitaxial crystal layer 29. In addition, the silicide layer 26 is formed on both sides of the gate sidewall 27 so as to contact with the gate sidewall 27. Therefore, the silicide layer 26 is formed on the upper surface of the epitaxial crystal layer 29, and does not contact with the semiconductor substrate 2.

### (Fabrication of Semiconductor Device)

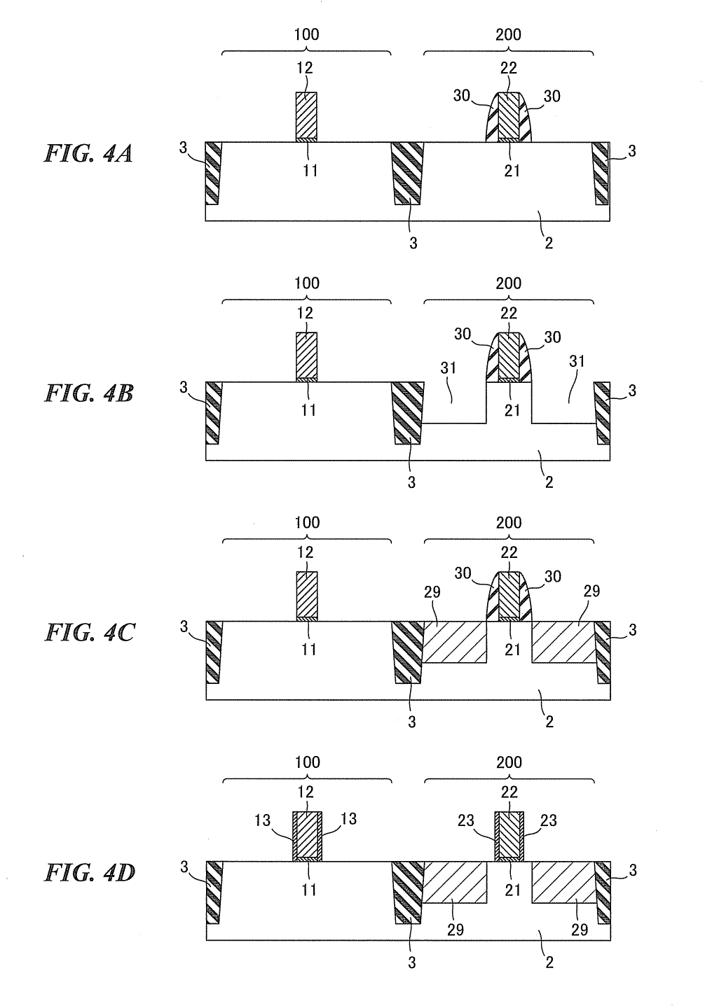

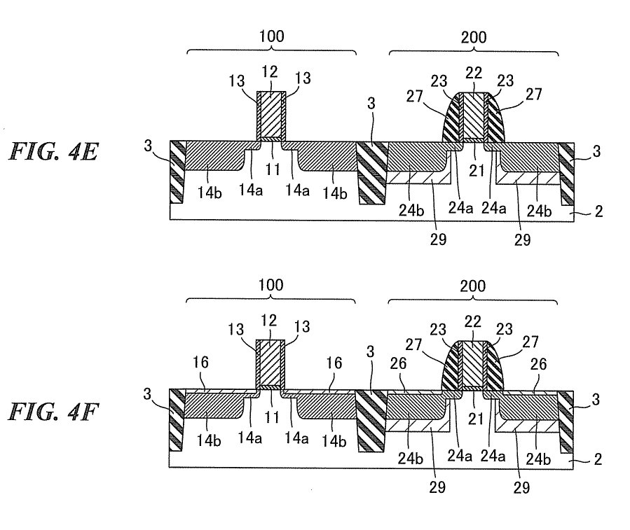

FIGS. 4A to 4F are cross sectional views showing processes for fabricating the semiconductor device according to the second embodiment.

Firstly, as shown in FIG. 4A, on the semiconductor substrate 2, after isolating the n-type transistor region 100 for forming the n-type transistor 10 from the p-type transistor region 200 for forming the p-type transistor 20 by forming the element isolation region 3, the gate insulating film 11 and the gate electrode 12 are formed in the n-type transistor region 100, and the gate insulating film 21, the gate electrode 22 and a dummy sidewall 30 are formed in the p-type transistor region 200.

Here, the dummy sidewall 30 is formed having a width smaller than that of the gate sidewall 27 which is formed in a posterior process. This is to prevent the silicide layer 26 from being formed in the semiconductor substrate 2.

Here, the dummy sidewall 30 is selectively formed only in the p-type transistor region 200. In detail, for example, after forming a dummy sidewall in the n-type transistor region 100 and in the p-type transistor region 200, only the dummy sidewall in the n-type transistor region 100 is removed by using the lithography method, etc. Then, after forming an insulating film made of SiO₂, etc., so as to cover the gate electrode 22, the dummy sidewall 30 is formed by etching and leaving the insulating film on the side face of the gate electrode 22.

Next, as shown in FIG. 4B, a trench 31 is formed by etching the p-type transistor region 200 of the semiconductor substrate 2 using the gate electrode 22 and the dummy sidewall 30 as a mask. At this time, the etching is conducted so as not to reach the n-type transistor region 100. In detail, for example, the etching is conducted, etc., after forming a resist using the lithography method in the n-type transistor region 100 of the semiconductor substrate 2.

Next, as shown in FIG. 4C, a crystal such as a SiGe crystal, etc., is epitaxially grown using the surface of the semiconductor substrate 2 exposed inside the trench 31 as a base, thereby forming the epitaxial crystal layer 29 in the p-type transistor region 200. When the SiGe crystal is formed as the epitaxial crystal layer 29, the epitaxial growth is conducted in a chemical vapor deposition chamber in an atmosphere such as, e.g., monosilane (SiH₄), germanium hydride (GeH₄) or hydrogen gas (H₂), etc., under the temperature condition of 700-750° C.

Next, as shown in FIG. 4D, after removing the dummy sidewall 30 by etching, the offset spacers 13 and 23 are formed on the side faces of the gate electrodes 12 and 22.

Note that, the offset spacer 23 is formed after removing the dummy sidewall 30 in the above-mentioned method, however, it may be possible to adopt a method in which the offset spacer 23 is formed and the dummy sidewall 30 is subsequently formed on the outside the offset spacer 23, and the dummy sidewall 30 is removed after forming the epitaxial crystal layer 29 under the condition that the offset spacer 23 is not removed.

Next, as shown in FIG. 4E, the processes from the formation of the extension regions 14a and 24a shown in FIG. 2B to the removing of the gate sidewall 17 shown in FIG. 2D are carried out in the same way as the first embodiment. Note that, the gate sidewall 27 has a width such that a portion thereof is located on the epitaxial crystal layer 29.

Next, as shown in FIG. 4F, the silicide layers 16 and 26 are formed. At this time, since the upper surface of the source/drain region 14 is exposed on both sides of the offset spacer 13, the silicide layer 16 is formed contacting with the offset spacer 13. Meanwhile, since the upper surface of the source/drain region 24 is exposed on both sides of the gate sidewall 27, the silicide layer 26 is formed contacting with the gate sidewall 27 (separating from the offset spacer 23). Since the gate sidewall 27 has a width such that a portion thereof is located on the epitaxial crystal layer 29, the silicide layer 26 is not formed in the semiconductor substrate 2.

### Effect of the Second Embodiment

According to the second embodiment, by forming the epitaxial crystal layer 29 which generates a strain in the channel region 25, it is possible to improve the hole mobility in the channel region 25 and the operation speed of the p-type transistor 20.

In addition, when the semiconductor substrate 2 is made of a Si crystal and the epitaxial crystal layer 29 is made of a SiGe crystal, if the silicide layer 26 is formed more closer to the gate electrode 22 and contacts with the semiconductor substrate 2, since a metal such as Ni, etc., composing the silicide layer 26 is more likely to react with Si than with Ge, leak may be generated by anomalous diffusion into the semiconductor substrate 2. According to the embodiment, since the gate sidewall 27 is formed in the p-type transistor 20 of which effect of improving the on-state current by the DSS structure is smaller than that of the n-type transistor 10 and the DSS structure is intentionally avoided, it is possible to prevent the silicide layer 26 from being formed in the semiconductor substrate 2.

On the other hand, it is possible to improve the performance of the n-type transistor 10 by not providing a gate sidewall in the n-type transistor 10 of which effect of improving the on-state current by the DSS structure is large, but configuring the n-type transistor 10 to have the DSS structure.

### Other Embodiments

It should be noted that the embodiment is not intended to be limited to the above-mentioned first to fourth embodiments, and the various kinds of changes thereof can be implemented by those skilled in the art without departing from the gist of the invention.

In addition, the constituent elements of the above-mentioned embodiments can be arbitrarily combined with each other without departing from the gist of the invention.

What is claimed is:

1. A semiconductor device, comprising:
an n-type transistor comprising a first gate electrode formed on a semiconductor substrate via a first gate insulating film, a first spacer formed on a side face of the first gate electrode, a first channel region formed in the semiconductor substrate under the first gate insulating film, a first source/drain region formed on both sides of the first channel region and comprising an extension region formed by a conductivity type impurity segregated on the first channel side, and a first silicide layer formed on the first source/drain region so as to contact with the first spacer;
a p-type transistor comprising a second gate electrode formed on the semiconductor substrate via a second gate insulating film, a second spacer formed on a side face of the second gate electrode, a gate sidewall formed on a side face of the second spacer, a second channel region formed in the semiconductor substrate under the second gate insulating film, a second source/drain region formed on both sides of the second channel region and comprising an extension region on the second channel region side, and a second silicide layer formed on the second source/drain region so as to separate from the second spacer;
a tensile stress film formed on the n-type transistor so as to contact with a side face of the first spacer for generating a tensile strain in channel direction in the first channel region; and
a compressive stress film formed on the p-type transistor so as to contact with a side face of the gate sidewall for generating a compressive strain in channel direction in the second channel region.

2. A semiconductor device, comprising:
an n-type transistor comprising a first gate electrode formed on a semiconductor substrate via a first gate insulating film, a first spacer formed on a side face of the first gate electrode, a first channel region formed in the semiconductor substrate under the first gate insulating film, a first source/drain region formed on both sides of the first channel region and comprising an extension region formed by a conductivity type impurity segregated on the first channel side, and a first silicide layer formed on the first source/drain region so as to contact with the first spacer; and
a p-type transistor comprising a second gate electrode formed on the semiconductor substrate via a second gate insulating film, a second spacer formed on a side face of the second gate electrode, a gate sidewall formed on a side face of the second spacer, a second channel region formed in the semiconductor substrate under the second gate insulating film, an epitaxial crystal layer formed on both sides of the second channel region, a second source/drain region formed on both sides of the second channel region so as to at least partially overlap with the epitaxial crystal layer and comprising an extension region on the second channel region side, and a second silicide layer formed on the second source/drain region so as to separate from the semiconductor substrate and the second spacer.

3. The semiconductor device according to claim 2, further comprising:
a tensile stress film formed on the n-type transistor so as to contact with a side face of the first spacer for generating a tensile strain in channel direction in the first channel region; and
a compressive stress film formed on the p-type transistor so as to contact with a side face of the gate sidewall for generating a compressive strain in channel direction in the second channel region.

4. The semiconductor device according to claim 1, wherein the first and second spacers are no less than 3 nm, nor more than 12 nm in thickness.

5. The semiconductor device according to claim 2, wherein the first and second spacers are no less than 3 nm, nor more than 12 nm in thickness.

6. The semiconductor device according to claim 1, wherein the second gate electrode comprises a metal electrode.

7. The semiconductor device according to claim 2, wherein the second gate electrode comprises a metal electrode.

8. The semiconductor device according to claim 2, wherein a channel direction of the second channel region is <110> or <100>; and
the epitaxial crystal layer comprises a crystal having a lattice constant larger than that of a crystal composing the semiconductor substrate.

9. The semiconductor device according to claim 2, wherein the semiconductor substrate comprises a Si crystal; and
the epitaxial crystal layer comprises a SiGe crystal.

10. The semiconductor device according to claim 2, wherein a portion of the gate sidewall is located on the epitaxial crystal layer.

11. A method of fabricating a semiconductor device, comprising:
respectively forming first and second gate electrodes in n-type and p-type transistor regions on a semiconductor substrate via gate insulating films;
forming first and second spacers on side faces of the first and second gate electrodes;
respectively forming extension regions of the first and second source/drain regions by implanting an impurity into the n-type and p-type transistor regions on the semiconductor substrate using the first and second spacers and the first and second gate electrodes as a mask;
selectively forming a gate sidewall on a side face of the second spacer;
respectively forming first and second silicide layers in a region exposed on both sides of the first spacer in the n-type transistor region and a region exposed on both sides of the gate sidewall in the p-type transistor region of the semiconductor substrate;
forming a tensile stress film including a tensile stress on the n-type and p-type transistor regions so as to contact with a side face of the first spacer and a side face of the gate sidewall;
selectively removing a portion of the tensile stress film located on the p-type transistor region; and
forming a compressive stress film including a compressive strain on the p-type transistor region so as to contact with the side face of the gate sidewall after selectively removing the portion of the tensile stress film located on the p-type transistor region.

12. The method of fabricating a semiconductor device according to claim 11, wherein the first and second spacers are formed, and subsequently, another gate sidewall and the gate sidewall are each formed on side faces of the first and second spacers;
deep regions of the first and second source/drain regions are each formed by implanting an impurity into the n-type and p-type transistor regions on the semiconductor substrate using the first and second spacers, the first and second gate electrodes, the other gate sidewall and the gate sidewall as a mask;
after forming the deep regions of the first and second source/drain regions, the other gate sidewall is removed while leaving the gate sidewall; and
the first and second silicide layers are formed after removing the other gate sidewall.

13. The method of fabricating a semiconductor device according to claim 11, wherein the tensile stress film and the compressive stress film are formed by a plasma CVD method.

14. The method of fabricating a semiconductor device according to claim 11, wherein a trench is formed on both sides of the gate electrodes in the p-type transistor region of the semiconductor substrate;
a predetermined crystal is epitaxially grown in the trench;
the first and second spacers are formed after epitaxially growing the predetermined crystal; and
the second silicide layer is formed in the predetermined crystal so as not to contact with the semiconductor substrate.

15. The method of fabricating a semiconductor device according to claim 14, wherein a dummy sidewall is formed on a side face of the second gate electrode;
the trench is formed by etching the p-type transistor region of the semiconductor substrate using the second gate electrode and the dummy sidewall as a mask;
the dummy sidewall is removed after epitaxially growing the predetermined crystal; and
the first and second spacers are formed after removing the dummy sidewall.

16. The method of fabricating a semiconductor device according to claim 15, wherein the dummy sidewall is formed so that a width thereof is narrower than that of the gate sidewall.

17. The method of fabricating a semiconductor device according to claim 14, wherein the predetermined crystal has a lattice constant larger than that of the crystal composing the semiconductor substrate.

18. The method of fabricating a semiconductor device according to claim 17, wherein the predetermined crystal is a SiGe crystal.

19. The method of fabricating a semiconductor device according to claim 15, wherein the first and second spacers are formed, and subsequently, another gate sidewall and the gate sidewall are each formed on side faces of the first and second spacers;
deep regions of the first and second source/drain regions are each formed by implanting an impurity into the n-type and p-type transistor regions on the semiconductor substrate using the first and second spacers, the first and second gate electrodes, the other gate sidewall and the gate sidewall as a mask;
after forming the deep regions of the first and second source/drain regions, the other gate sidewall is removed while leaving the gate sidewall; and
the first and second silicide layers are formed after removing the other gate sidewall.

20. The method of fabricating a semiconductor device according to claim 15, wherein the tensile stress film and the compressive stress film are formed by a plasma CVD method.
